(19) United States
(12) Patent Application Publication
(10) Pub. No.: US 2024/0107742 A1
(43) Pub. Date: Mar. 28, 2024

(54) SEMICONDUCTOR MEMORY DEVICE

(71) Applicant: Winbond Electronics Corp., Taichung City (TW)

(72) Inventors: Frederick CHEN, Tainan City (TW); Yoshinori TANAKA, Taichung City (TW); Noriaki IKEDA, Taichung City (TW)

(21) Appl. No.: 17/952,657

(22) Filed: Sep. 26, 2022

(51) Int. Cl. H01L 27/108

(52) U.S. Cl. CPC H01L 27/10805; H01L 27/10897

(57) ABSTRACT

A semiconductor memory device includes a substrate, and a plurality of layers vertically stacked over the substrate. A first layer in the plurality of layers includes an active region extending in a first direction parallel to a top surface of the substrate. The semiconductor memory device also includes a first conductive line that extends vertically in a second direction perpendicular to the top surface of the substrate and penetrates through the active region. The semiconductor memory device also includes a capacitor including a first electrode that is disposed in the active region.

### BACKGROUND

### Field of the Disclosure

The present disclosure relates to a semiconductor memory device, and in particular, it relates to Dynamic Random Access Memory with a three-dimensional structure.

### Description of the Related Art

In order to achieve an improvement in the degree of integration of memory cells, a DRAM with a three-dimensional structure in which an array of memory cells is stacked in a direction perpendicular to the main surface of the substrate becomes a potential candidate.

### SUMMARY

In some embodiments of the disclosure, a semiconductor memory device is provided. The semiconductor memory device includes a substrate, and a plurality of layers vertically stacked over the substrate. A first layer in the plurality of layers includes an active region extending in a first direction parallel to a top surface of the substrate. The semiconductor memory device also includes a first conductive line that extends vertically in a second direction perpendicular to the top surface of the substrate and penetrates through the active region. The semiconductor memory device also includes a capacitor including a first electrode that is disposed in the active region.

In some embodiments of the disclosure, a semiconductor memory device is provided. The semiconductor memory device includes a plurality of memory cell transistors vertically stacked over a substrate. Each of the memory cell transistors includes an active region and a gate electrode layer. The semiconductor memory device also includes a first conductive line that extends vertically in a first direction perpendicular to a top surface of the substrate and penetrates through first source/drain regions of the active regions. The semiconductor memory device also includes a plurality of second conductive lines extending in a second direction parallel to the top surface of the substrate. Each of the second conductive lines is electrically connected to a respective gate electrode layers.

In some embodiments of the disclosure, a semiconductor memory device is provided. The semiconductor memory device includes a first active region which includes a first source/drain region, a first channel region, a second source/drain region, a second channel region, and a third source/drain region sequentially arranged in a first direction. The semiconductor memory device also includes a bit line vertically penetrating through, and electrically connected to, the second source/drain region of the first active region. The semiconductor memory device also includes a first capacitor disposed in the first source/drain region of the first active region, and a second capacitor disposed in the third source/drain region of the first active region.

### BRIEF DESCRIPTION OF THE DRAWINGS

In accordance with some embodiments of the present disclosure, it can be further understood by reading the subsequent detailed description and examples with references made to the accompanying drawings, wherein:

FIG. 1 is a circuit diagram schematically illustrating a three-dimensional semiconductor memory device, in accordance with some embodiments.

FIG. 2A is a perspective view illustrating a three-dimensional semiconductor memory device, in accordance with some embodiments.

FIG. 2B is a plan view of the three-dimensional semiconductor memory device illustrating a portion A as shown in FIG. 2A, in accordance with some embodiments.

FIG. 2C is a cross-sectional view of the three-dimensional semiconductor memory device taken along line I-I as shown in FIG. 2B, in accordance with some embodiments.

FIG. 3 is a modification of the three-dimensional semiconductor memory device of FIG. 2B, in accordance with some embodiments.

### DETAILED DESCRIPTION

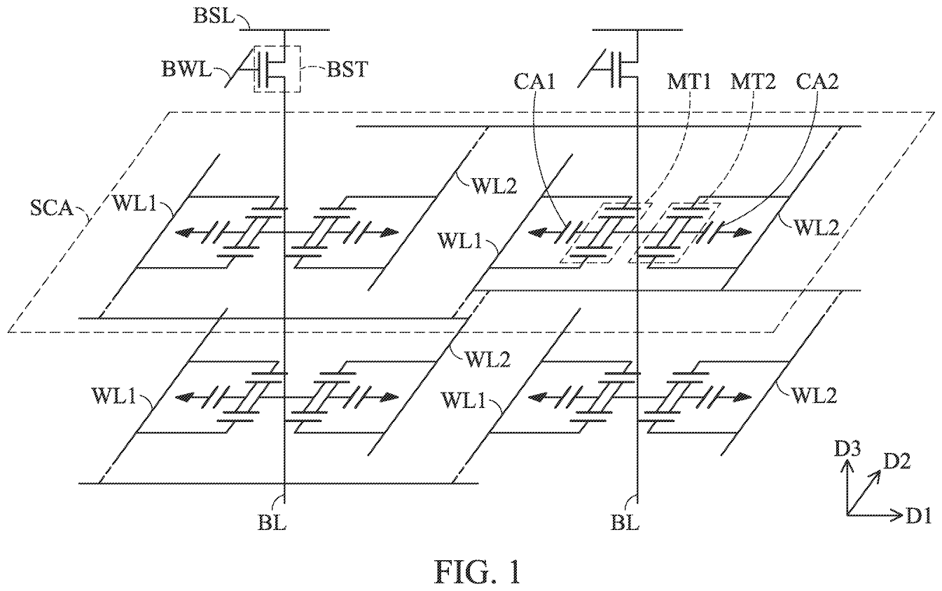

FIG. 1 is a circuit diagram schematically illustrating a three-dimensional semiconductor memory device, in accordance with some embodiments. In some embodiments, the semiconductor memory device includes a DRAM device with a three-dimensional structure. In some embodiments, the semiconductor memory device is formed over a substrate. For ease of illustration, FIG. 1 illustrates reference directions, in that the first direction D1 and the second direction D2 are horizontal directions parallel to the top surface of the substrate, and the third direction D3 is a vertical direction perpendicular to the top surface of the substrate. The first direction D1 is substantially perpendicular to the second direction D2.

The semiconductor memory device includes a cell array which includes a plurality of sub-cell arrays SCA. The sub-cell arrays SCA are vertically stacked over the substrate in the third direction D3. Each sub-cell array SCA includes a plurality of first word lines WL1, a plurality of second word lines WL2, pairs of memory transistors MT1, pairs of memory transistors MT2, a plurality of first capacitors CA1 and a plurality of second capacitors CA2. The semiconductor memory device also includes a plurality of bit lines BL. The bit lines BL extend from the substrate in the third direction D3 and pass through the sub-cell arrays SCA.

The first word lines WL1 and the second word lines WL2 extend in the second direction D2. Alternating first word lines WL1 and second word lines WL2 are arranged in the first direction D1. The first word lines WL1 and the second word lines WL2 are spaced apart and electrically isolated from one another. Each of the bit lines BL is interposed between a first word line WL1 and the adjacent second word line WL2. In some embodiments, the first word lines WL1 may be electrically connected to one another, and the second word lines WL2 may be electrically connected to one another.

A pair of first memory transistors MT1 and a pair of second memory transistors MT2 are disposed adjacent to each other and between a first word line WL1 and the adjacent second word line WL2. The gate terminals of each pair of first memory transistors MT1 are electrically connected to a corresponding first word line WL1, and the gate terminals of each pair of second memory transistors MT2 are electrically connected to a corresponding second word line WL2.

Two first memory transistors MT1 share a first source/drain terminal (e.g., drain terminals) which is electrically connected to an electrode of a first capacitor CA1. Two first memory transistors MT1 and two second memory transistors MT2 adjacent thereto share a second source/drain terminal (e.g., source terminals) which is electrically connected one bit line BL. Two second memory transistors MT2 share a third source/drain terminal (e.g., drain terminals) which is electrically connected to an electrode of a second capacitor CA2.

The semiconductor memory device also includes a plurality of bit line select transistors BST, a plurality of bit line select word lines BWL, and a plurality of bit line select source lines BSL which are disposed above the sub-cell arrays SCA. Each bit line select transistor BST has a first source/drain terminal which is electrically connected to a corresponding bit line BL. Each bit line select transistor BST has a gate terminal which is electrically connected to a corresponding bit line select word line BWL. Each bit line select transistor BST has a second source/drain terminal which is electrically connected to a corresponding bit line select source line BSL.

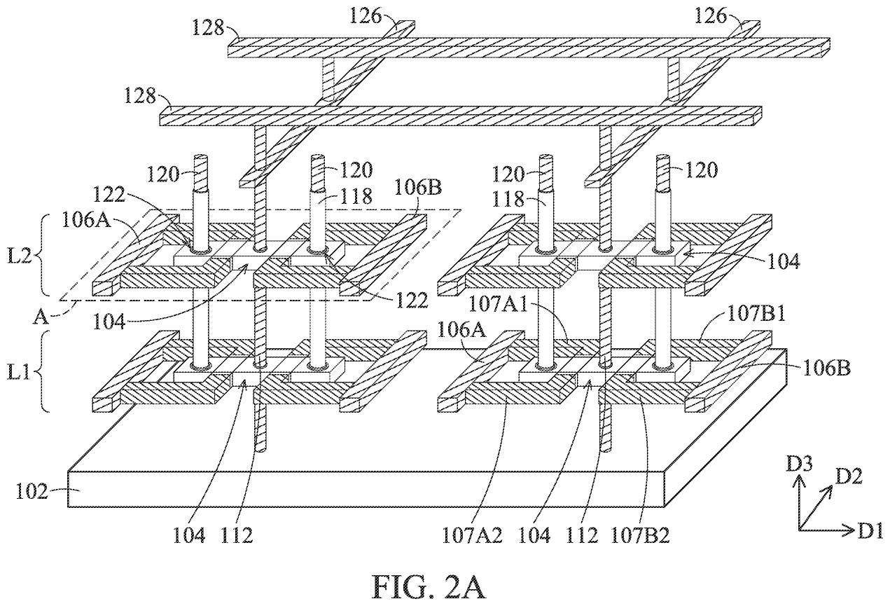

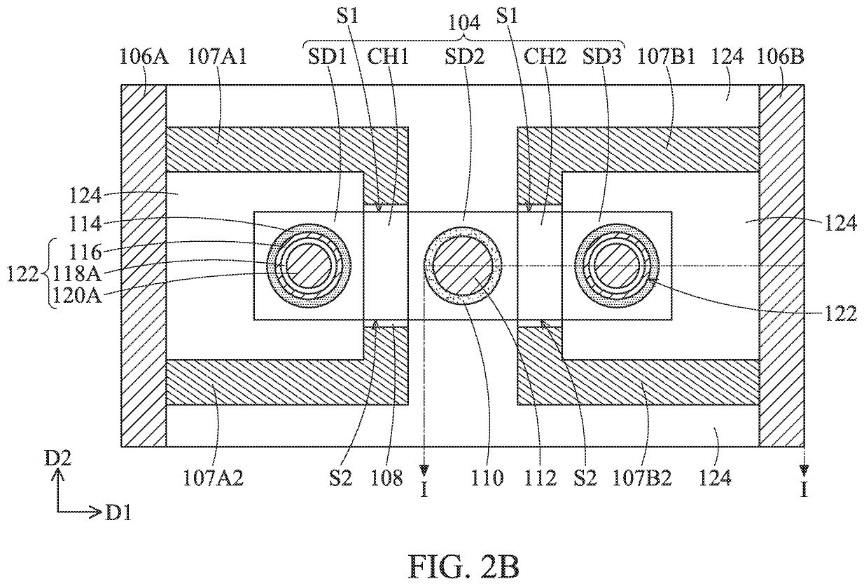

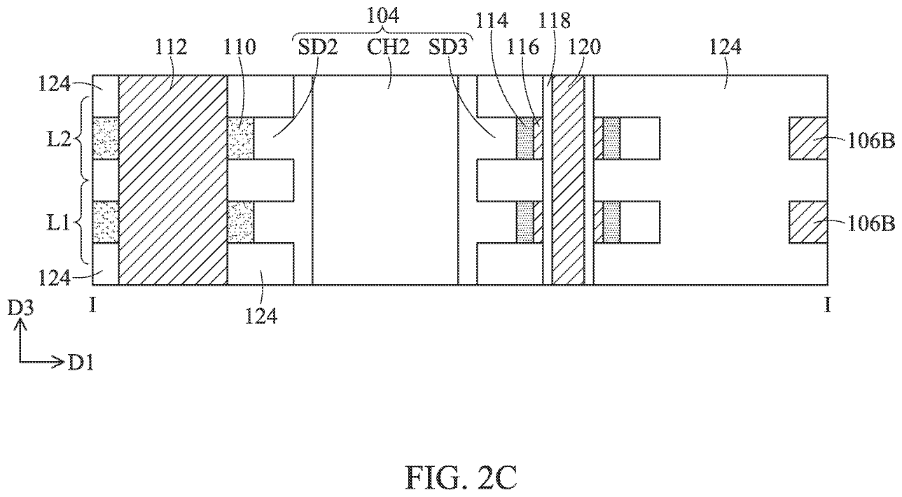

FIG. 2A is a perspective view illustrating a three-dimensional semiconductor memory device, in accordance with some embodiments. FIG. 2B is a plan view of the three-dimensional semiconductor memory device illustrating a portion A as shown in FIG. 2A, in accordance with some embodiments. FIG. 2C is a cross-sectional view of the three-dimensional semiconductor memory device taken along line I-I as shown in FIG. 2B, in accordance with some embodiments.

The three-dimensional semiconductor memory device shown in FIGS. 2A, 2B and 2C may be the semiconductor memory device as discussed above in FIG. 1. The semiconductor memory device is formed over a substrate 102, as shown in FIG. 2A. In some embodiments, the substrate 102 may be or includes a semiconductor substrate (e.g., Si substrate).

The semiconductor memory device includes a stack in which layers L1 and L2 are vertically stacked over the substrate 102 in the third direction D3. The layers L1 and L2 may be the sub-cell arrays SCA as discussed above in FIG. 1. Although FIG. 2A only illustrates two layers, the semiconductor memory device may include more than two layers, e.g., 3-20. Each of the layers L1 and L2 includes a plurality of first conductive lines 106A, a plurality of second conductive lines 106B, a plurality of gate electrode layers 107A1, 107A2, 107B1, and 107B2, a plurality of active regions 104, and a plurality of capacitor 122, as shown in FIGS. 2A-2C. The layers L1 and L2 are horizontal layers, and those components in a layer L1 or L2 are located at substantially the same level.

The semiconductor memory device also includes a plurality of third conductive lines 112, a plurality of dielectric tubes 118, and a plurality of fourth conductive lines 120, which extend from the substrate 102 in the third direction D3 and vertically penetrates through the layers (e.g., L1 and L2) of the stack. Each fourth conductive line 120 is wrapped in a corresponding dielectric tube 118.

Although not shown in FIG. 2A, the semiconductor memory device may also include one or more dielectric layer 124, as shown in FIGS. 2B and 2C. The dielectric layer 124 fills the remaining space of the semiconductor memory device. In some embodiments, the dielectric layer 124 may be made of silicon oxide (SiO), silicon nitride (SiN), silicon oxynitride (SiON), and/or a combination thereof.

The first conductive line 106A and the second conductive line 106B respectively serve as the first word lines WL1 and the second word lines WL2 as discussed above in FIG. 1. The first conductive lines 106A and the second conductive lines 106B extend in the second direction D2. That is, the dimensions (lengths) of the first conductive lines 106A and the second conductive lines 106B in the second direction D2 are greater than the dimensions (widths) of the first conductive lines 106A and the second conductive lines 106B in the first direction D1. The first conductive lines 106A and the second conductive lines 106B are alternatingly arranged in the first direction D1.

In some embodiments, the conductive lines 106A and 106B are made of an electrically conductive material such as doped semiconductor material (such as polysilicon), metal material (such as tungsten (W), aluminum (Al), copper (Cu), cobalt (Co), or ruthenium (Ru)), or metal nitride (such as titanium nitride (TiN) or tantalum nitride (TaN)), and/or a combination thereof.

Each active region 104 is disposed between a first conductive line 106A and the adjacent second conductive line 106B. The active regions 104 extend in the first direction D1. That is, the dimensions (lengths) of the active regions 104 in the first direction D1 are greater than the dimensions (widths) of the active regions 104 in the second direction D2. The active regions 104 are made of doped semiconductor material (e.g., polysilicon). As shown in FIG. 2C, the active regions 104 stacked vertically each other may be formed from a continuous semiconductor material.

Each active region 104 includes or is defined as a first source/drain region SD1, a first channel region CHL a second source/drain region SD2, a second channel region CH2, and a third source/rain region SD3, as shown FIG. 2B. In some embodiments, the source/drain regions SD1, SD2 and SD3 may have a different conductivity type than the channel regions CH1 and CH2. For example, the source/drain regions SD1, SD2 and SD3 are doped with n-type dopants, and the channel regions CH1 and CH2 are doped with p-type dopants.

As shown in FIG. 2B, the source/drain regions SD1, SD2 and SD3 are surrounded by and in direct contact with the dielectric layer 124. As shown in FIG. 2C, the upper surfaces and the bottom surfaces of the source/drain regions SD1, SD2 and SD3 are covered by and in direct contact with the dielectric layer 124.

The active regions 104 have opposite sides (or sidewalls) S1 and S2 with respect to the second direction D2, as shown in FIG. 2B. The first gate electrode layers 107A1 are electrically coupled to the first channel regions CH1 of the active regions 104 on the first side S1. The second gate electrode layers 107A2 are electrically coupled to the first channel regions CH1 of the active regions 104 on the second side S2. The third gate electrode layers 107B1 are electrically coupled to the second channel regions CH2 of the active regions 104 on the first side S1. The fourth gate electrode layers 107B are electrically coupled to the second channel regions CH2 of the active regions 104 on the second side S2.

The first and second gate electrode layers 107A1 and 107A2 are electrically connected to the first conductive lines 106A, and the third and fourth gate electrode layers 107A3 and 107A4 are electrically connected to the second conductive lines 106B. As shown in FIG. 2B, the gate electrode layers 107A1, 107A2, 107B1 and 107B2 may have L-shape profiles, with first segments (extending in the first direction D1) connected to the conductive lines 106A and 106B and second segments (extending in the second direction D2) connected to the active regions 104.

The gate dielectric layers 108 are disposed between the gate electrode layers 107A1, 107A2, 107B1 and 107B2 and the active regions 104, and combined with the gate electrode layers 107A1, 107A2, 107B1 and 107B2 to serve as gate structures. The gate structures including the first and second gate electrode layers 107A1 and 107A2 combine with the source/drain regions SD1 and SD2 to form a pair of first memory transistors MT1 as discussed above in FIG. 1. The gate structures including the third and fourth gate electrode layers 107B1 and 107B2 combine with the source/drain regions SD2 and SD3 to form a pair of second memory transistors MT2 as discussed above in FIG. 1.

In some embodiments, the gate electrode layers 107A1, 107A2, 107B1 and 107B2 are made of an electrically conductive material such as doped semiconductor material (such as polysilicon), metal material (such as tungsten (W), aluminum (Al), copper (Cu), cobalt (Co), or ruthenium (Ru)), or metal nitride (such as titanium nitride (TiN) or tantalum nitride (TaN)), and/or a combination thereof. In some embodiments, the first conductive lines 106A and the first and second gate electrode layers 107A1 and 107A2 may be made of a continuous metal material, and the second conductive lines 106B and the third and fourth gate electrode layers 107B1 and 107B2 may be made of a continuous metal material. In some other embodiments, the gate electrode layers 107A1, 107A2, 107B1 and 107B2 are made of semiconductor material (e.g., polysilicon), and the conductive lines 106A and 106B are made of metal material.

The third conductive lines 112 serve as the bit lines BL as discussed above in FIG. 1. The third conductive lines 112 penetrate through the second source/drain regions SD2 of the active regions 104, as shown in FIGS. 2A, 2B and 2C. The contacts 110 are disposed between the second source/drain regions SD2 of the active regions 104 and the third conductive lines 112. The third conductive lines 112 are electrically connected to the second source/drain regions SD2 through the contacts 110.

As shown in FIG. 2B, each contact 110 has a ring-shape profile, and a corresponding third conductive line 112 is located within the ring-shape profile of the contact 110. As shown in FIG. 2C, the upper surface and the bottom surface of the contact 110 are covered by and in direct contact with the dielectric layer 124. The portions of the third conductive lines 112 outside the active regions 104 are surrounded by, and in direct contact with, the dielectric layer 124.

In some embodiments, third conductive lines 112 and the contacts 110 are made of doped semiconductor material (such as polysilicon), metal material (such as tungsten (W), aluminum (Al), copper (Cu), cobalt (Co), or ruthenium (Ru)), or metal nitride (such as titanium nitride (TiN) or tantalum nitride (TaN)), and/or a combination thereof. In some embodiments, the third conductive lines 112 are made of metal material, and the contacts 110 are made of doped semiconductor material.

The capacitors 122 may be the capacitors CA1 and CA2 as discussed above in FIG. 1. The capacitors 122 are disposed within the first source/drain region SD1 and the third source/drain region SD3 of the active regions 104, as shown in FIGS. 2A-2C. Each capacitor 122 includes a first electrode 116, a capacitor dielectric layer 118A and a second electrode 120A. The portions of the dielectric tubes 118 surrounded by the active regions 104 serve as the capacitor dielectric layers 118A, and the portions of the fourth conductive lines 120 surrounded by the active regions 104 serve as the second electrodes 120A.

The contacts 114 are disposed between the first electrode 116 and first source/drain region SD1 (or the third source/drain region SD3) of the active regions 104. The first electrodes 116 are electrically connected to the first source/drain regions SD1 (or the third source/drain regions SD3) through the contacts 114. As shown in FIG. 2B, the contact 114, the first electrode 116 and the capacitor dielectric layer 118A have respective ring-shape profiles, and the second electrode 120A is located within the ring-shape profile of the capacitor dielectric layer 118A. In some embodiments, the ring-shape profiles of the contact 114, the first electrode 116 and the capacitor dielectric layer 118A may be concentric. As shown in FIG. 2C, the upper surfaces and the bottom surfaces of the contact 114 and the first electrodes 116 are covered by and in direct contact with the dielectric layer 124. The portions of the dielectric tubes 118 outside the active regions 104 are surrounded by, and in direct contact with, the dielectric layer 124.

In some embodiments, the contacts 114, the first electrodes 116, and the fourth conductive lines 120 (or the second electrodes 120A) are made of an electrically conductive material such as doped semiconductor material (such as polysilicon), metal material (such as tungsten (W), aluminum (Al), copper (Cu), cobalt (Co), or ruthenium (Ru)), or metal nitride (such as titanium nitride (TiN) or tantalum nitride (TaN)), and/or a combination thereof. In some embodiments, the first electrodes 116 are made of metal material, and the contacts 114 are made of doped semiconductor material. The dielectric tubes 118 (or the capacitor dielectric layers 118A) are made of silicon oxide, hafnium oxide, zirconium oxide, aluminum oxide, lanthanum oxide, tantalum oxide, titanium oxide, another suitable dielectric material, and/or a combination thereof.

The semiconductor memory device also includes a plurality of fifth conductive lines 126 and a plurality of sixth conductive lines 128. The fifth conductive lines 126 and the sixth conductive lines 128 respectively serve as the bit line select word lines BWL and the bit line select source lines BSL as discussed above in FIG. 1. The fifth conductive lines 126 extend in the second direction D2, and the sixth conductive lines 128 extend in the first direction D1.

The semiconductor memory device may include semiconductor patterns (not shown) surrounded by the fifth conductive lines 126, thereby forming a plurality of bit line select transistors (e.g., BST in FIG. 1) above the stack of the semiconductor memory device. In some embodiments, the fifth conductive lines 126 and the sixth conductive lines 128 are made of an electrically conductive material such as doped semiconductor material (such as polysilicon), metal material (such as tungsten (W), aluminum (Al), copper (Cu), cobalt (Co), or ruthenium (Ru)), or metal nitride (such as titanium nitride (TiN) or tantalum nitride (TaN)), and/or a combination thereof.

As the scale of semiconductor memory devices continues to shrink, and the spacing of the word lines becomes smaller and smaller, one of the design challenges of forming a semiconductor memory device is to reduce the Row hammer effect. In accordance with the embodiments, bit lines BL (i.e., the third conductive lines 112) are interposed between the adjacent word lines WL1 and WL2 (i.e., the first conductive lines 106A and the second conductive lines 106B). As a result, when applying a voltage to one word line (e.g., WL1) to access the semiconductor memory device, the bit line BL1 may reduce interference from the voltage being applied to another word line (e.g., WL2), and thus the Row hammer effect may be reduced. Therefore, the performance of the semiconductor memory device may be improved (e.g., better data retention).

In addition, in some instances where the channel regions of the active regions are annularly wrapped (e.g., by four sides) by the gate electrode layers, the current (e.g., drain current) may drop rapidly as the size of the channel regions shrink. In accordance with the embodiments, the gate electrode layer 107A1, 107A2, 107B1 and 107B2 are electrically coupled to the two sides of the channel regions, which may significantly slow down the rate of the current drops caused by the size reduction of the channel regions. Therefore, the embodiments of the present disclosure may facilitate the scaling of the semiconductor memory device.

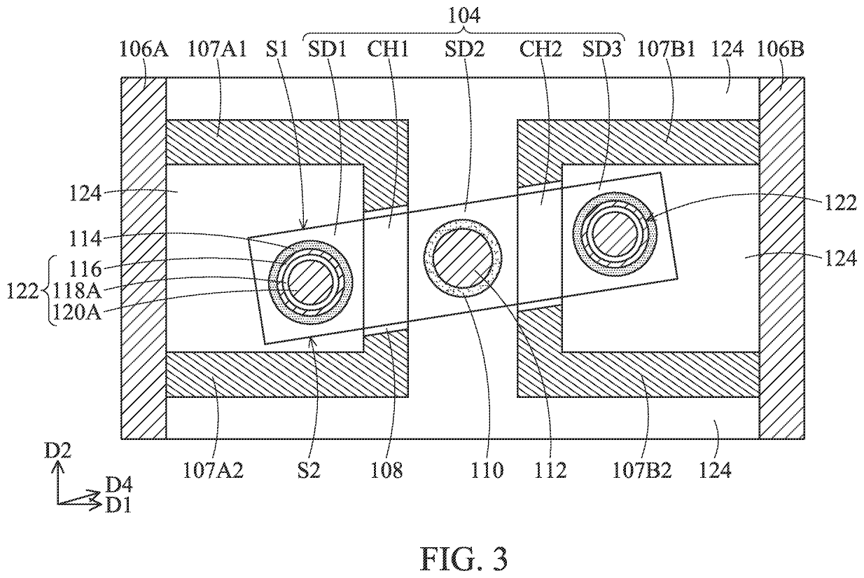

FIG. 3 is a modification of the three-dimensional semiconductor memory device of FIG. 2B, in accordance with some embodiments. The semiconductor memory device of FIG. 3 is similar to the semiconductor memory device of FIG. 2B, except for the active region 104. The cell density of the semiconductor memory device can be adjusted by adjusting the axial direction of the active region.

As shown in FIG. 3, the active regions 104 extend in a fourth direction D4. The fourth direction D4 is not perpendicular to the first direction D1. For example, the fourth direction D4 meets the first direction D1 an acute angle, e.g., in a range from about 5 degrees to about 45 degrees. In some embodiments, the axial direction of the active region 104 can be rotated while maintaining source/drain regions SD1 and SD3 of the active regions 104 separated from the gate electrode layers 107A1, 107A2, 107B1 and 107B2 by the dielectric layer 124. Therefore, the embodiments may provide greater flexibility in adjusting the cell density.

As described above, the embodiments of the present disclosure provide an architecture for a three-dimensional DRAM device, which may mitigate the constraints (e.g., Row hammer effect, decreasing in drain current, etc.) of scaling-down the device size. Therefore, the degree of integration of the memory cells may be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device, comprising:
a substrate;
a plurality of layers vertically stacked over the substrate, wherein a first layer in the plurality of layers comprises an active region extending in a first direction parallel to a top surface of the substrate;
a first conductive line vertically extending in a second direction perpendicular to the top surface of the substrate and penetrating through the active region; and
a capacitor comprising a first electrode that is disposed in the active region.

2. The semiconductor memory device as claimed in claim 1, wherein the active region includes a first source/drain region, a channel region and a second source/drain region, and the first conductive line penetrates through the second source/drain region of the active region.

3. The semiconductor memory device as claimed in claim 2, wherein the first layer further comprises:
a second conductive line extending in a third direction that is parallel to the top surface of the substrate.

4. The semiconductor memory device as claimed in claim 3, wherein the first layer further comprises:
a first gate electrode layer connected to the second conductive line and electrically coupled to a first side of the channel region of the active region.

5. The semiconductor memory device as claimed in claim 4, wherein the first layer further comprises:
a second gate electrode layer connected to the second conductive line and electrically coupled to a second side of the channel region of the active region that is opposite the first side of the channel region.

6. The semiconductor memory device as claimed in claim 3, wherein the first direction is neither parallel nor perpendicular to the third direction.

7. The semiconductor memory device as claimed in claim 2, further comprising:
a third conductive line vertically extending in the second direction and penetrating through the first source/drain region of the active region.

8. The semiconductor memory device as claimed in claim 7, wherein the capacitor comprises a second electrode that includes a portion of the third conductive line surrounded by the active region, and in a plan view, the second electrode is located within the first electrode.

9. A semiconductor memory device, comprising:
a plurality of memory cell transistors vertically stacked over a substrate, each of the memory cell transistors comprising an active region and a gate electrode layer;
a first conductive line vertically extending in a first direction perpendicular to a top surface of the substrate and penetrating through first source/drain regions of the plurality of active regions; and
a plurality of second conductive lines extending in a second direction parallel to the top surface of the substrate, wherein each of the second conductive lines is electrically connected to a respective gate electrode layer.

10. The semiconductor memory device as claimed in claim 10, further comprising:
a plurality of capacitors disposed in second source/drain regions of the plurality of active regions.

11. The semiconductor memory device as claimed in claim 10, further comprising:
a dielectric layer surrounding the second source/drain regions of the plurality of active regions.

12. The semiconductor memory device as claimed in claim 11, wherein each of the capacitors includes a capacitor dielectric layer, and the plurality of capacitor dielectric layers are made of a continuous dielectric tube that extends in the first direction.

13. The semiconductor memory device as claimed in claim 12, wherein the continuous dielectric tube has a sidewall interfaced with the dielectric layer.

14. The semiconductor memory device as claimed in claim 9, further comprising:
a select transistor disposed above the plurality of memory cell transistors.

15. The semiconductor memory device as claimed in claim 9, wherein in a plan view, one of the gate electrode layers has an L-shape.

16. A semiconductor memory device, comprising:
a first active region including a first source/drain region, a first channel region, a second source/drain region, a second channel region, and a third source/drain region sequentially arranged in a first direction;
a bit line vertically penetrating through and electrically connected to the second source/drain region of the first active region;
a first capacitor disposed in the first source/drain region of the first active region; and
a second capacitor disposed in the third source/drain region of the first active region.

17. The semiconductor memory device as claimed in claim 16, further comprising:
a contact sandwiched between the first capacitor and the first source/drain region of the first active region, wherein in a plan view, the contact has a ring-shape profile, and the first capacitor is located within the ring-shape profile of the contact.

18. The semiconductor memory device as claimed in claim 16, further comprising:
a second active region vertically stacked over the first active region, wherein the bit line penetrates through the second active region.

19. The semiconductor memory device as claimed in claim 16, further comprising:
a first gate structure and a second gate structure respectively abutting the first channel region and the second channel region of the first active region at a first side of the first active region; and
a third gate structure and a fourth gate layer respectively abutting the first channel region and the second channel region of the first active region at a second side of the first active region, wherein the second side is opposite the first side.

20. The semiconductor memory device as claimed in claim 19, further comprising:
a first word line electrically connected to gate electrodes of the first gate structure and the third gate structure; and
a second word line electrically connected to gate electrodes of the second gate structure and the fourth gate structure.
